(19) United States
(12) Patent Application Publication
(10) Pub. No.: US 2010/0080275 A1
(43) Pub. Date: Apr. 1, 2010

(54) TRAINING OF THE NON-UPDATED DECISION FEEDBACK EQUALIZER FOR A 8-VSB RECEIVER

(75) Inventors: Lin Yang, Fremont, CA (US); Jun Lu, Saratoga, CA (US); Shue-Lee Chang, San Jose, CA (US); Jing Li, San Jose, CA (US); Syang-Myau Hwang, Cupertino, CA (US)

Correspondence Address: FRANK F. TIAN, 331-4A THIRD AVENUE, LONG BEACH, NJ, 07740, US

(73) Assignee: LEGEND SILICON CORP., Fremont, CA (US)

(21) Appl. No.: 12/239,794

(22) Filed: Sep. 28, 2008

(51) Int. Cl. H03H 7/30; H03H 7/40

(52) U.S. Cl. 375/231; 375/233; 375/346

(57) ABSTRACT

A method for training of a non-updated decision feedback equalizer is provided. The method comprising the steps of: providing a sequence of frames adapted to be received by a receiver; provide a sequence of synchronization frames interposed between a predetermined number of frames; and using at least part of the sequence of synchronization frames to train a decision feedback equalizer (DFE), thereby speeding up system convergence or making system convergence possible.

### CROSS-REFERENCE TO OTHER APPLICATIONS

The following applications of common assignee and filed on the same day herewith are related to the present application, and are herein incorporated by reference in their entireties:

U.S. patent application Ser. No. ______ with attorney docket number LSFFT-102.

U.S. patent application Ser. No. ______ with attorney docket number LSFFT-103.

U.S. patent application Ser. No. ______ with attorney docket number LSFFT-104.

U.S. patent application Ser. No. ______ with attorney docket number LSFFT-105.

U.S. patent application Ser. No. ______ with attorney docket number LSFFT-106.

U.S. patent application Ser. No. ______ with attorney docket number LSFFT-107.

### FIELD OF THE INVENTION

The present invention relates generally to digital filters, more specifically the present invention relates to training of a non-updated decision feedback equalizer.

### BACKGROUND

Electronic equipment and supporting software applications typically involve signal processing. For example, home theater, computer graphics, medical imaging and telecommunications all rely on signal-processing technology. Signal processing requires fast math in complex, but repetitive algorithms. Many applications require computations in real-time, i.e., the signal is a continuous function of time, which need be sampled and converted to digital, for numerical processing. A signal processor has to execute algorithms performing discrete computations on the samples as they arrive. The architecture of a digital signal processor (DSP) is optimized to handle such algorithms. The characteristics of a good signal processing engine typically may include fast, flexible arithmetic computation units, unconstrained data flow to and from the computation units, extended precision and dynamic range in the computation units, dual address generators, efficient program sequencing, and ease of programming.

For wireless receivers, time domain multi-path effect exists, a digital filter such as a non-updated decision feedback equalizer is required to filter out the undesirable information. Therefore, it is desirous to improve digital filter circuit structure with a training of a non-updated decision feedback equalizer using exiting data structure of a communications system.

### SUMMARY OF THE INVENTION

A method for training of a non-updated decision feedback equalizer for a VSB receiver is provided.

A method for training of a non-updated decision feedback equalizer for multi-leveled VSB receiver is provided.

A method for training of a non-updated decision feedback equalizer for 8-VSB receiver is provided.

A method for training of a non-updated decision feedback equalizer is provided. The method comprising the steps of: providing a sequence of frames adapted to be received by a receiver; provide a sequence of synchronization frames interposed between a predetermined number of frames; and using at least part of the sequence of synchronization frames to train a decision feedback equalizer (DFE), thereby speeding up system convergence or making system convergence possible.

### BRIEF DESCRIPTION OF THE FIGURES

The accompanying figures, where like reference numerals refer to identical or functionally similar elements throughout the separate views and which together with the detailed description below are incorporated in and form part of the specification, serve to further illustrate various embodiments and to explain various principles and advantages all in accordance with the present invention.

FIG. 1 is an example of an equalizer structure in accordance with some embodiments of the invention.

FIG. 2 is a first example of a sequence of frames in accordance with some embodiments of the invention.

FIG. 2A is a second example of a sequence of frames in accordance with some embodiments of the invention.

FIG. 3 is flowchart in accordance with some embodiments of the invention.

FIG. 4 is an example of a digital receiver in accordance with some embodiments of the invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION

Before describing in detail embodiments that are in accordance with the present invention, it should be observed that the embodiments reside primarily in combinations of method steps and apparatus components related to training of a non-updated decision feedback equalizer for a VSB receiver. Accordingly, the apparatus components and method steps have been represented where appropriate by conventional symbols in the drawings, showing only those specific details that are pertinent to understanding the embodiments of the present invention so as not to obscure the disclosure with details that will be readily apparent to those of ordinary skill in the art having the benefit of the description herein.

In this document, relational terms such as first and second, top and bottom, and the like may be used solely to distinguish one entity or action from another entity or action without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “comprises . . . a” does not, without more constraints, preclude the existence of additional identical elements in the process, method, article, or apparatus that comprises the element.

It will be appreciated that embodiments of the invention described herein may be comprised of one or more conventional processors and unique stored program instructions that control the one or more processors to implement, in conjunction with certain non-processor circuits, some, most, or all of the functions of using known sequences within the guard intervals being used for training of a non-updated decision feedback equalizer for a VSB receiver. The non-processor circuits may include, but are not limited to, a radio receiver, a radio transmitter, signal drivers, clock circuits, power source circuits, and user input devices. As such, these functions may be interpreted as steps of a method to training of a non-updated decision feedback equalizer for a VSB receiver. Alternatively, some or all functions could be implemented by a state machine that has no stored program instructions, or in one or more application specific integrated circuits (ASICs), in which each function or some combinations of certain of the functions are implemented as custom logic. Of course, a combination of the two approaches could be used. Thus, methods and means for these functions have been described herein. Further, it is expected that one of ordinary skill, notwithstanding possibly significant effort and many design choices motivated by, for example, available time, current technology, and economic considerations, when guided by the concepts and principles disclosed herein will be readily capable of generating such software instructions and programs and ICs with minimal experimentation.

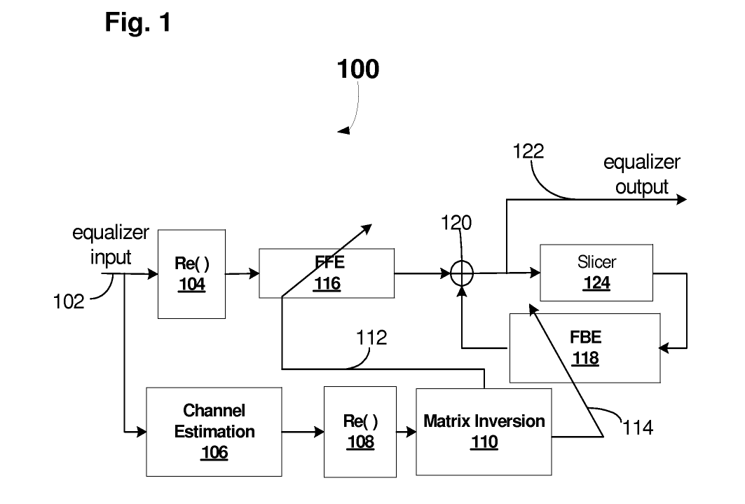

Referring to FIG. 1, a Non-updated Decision Feedback Equalizer 100 is shown. An equalizer input 102 is both input into a real part extractor 104 and a channel estimation block 106. In real part extractor 104, the real portion (versus the imaginary portion) of input 102 is extracted. In channel estimation block 106, both real and imaginary portions of the channel estimation block 106 are subjected to channel estimation. The estimated information is fed into real part extractor 108, the real portion (versus the imaginary portion) of input estimated information is extracted. In turn, the real portion of the estimated information is input into a matrix inversion block 110, wherein a matrix denoting the real portion of the estimated information is inverted.

Matrix inversion block 110 generates two adjustment paths, a first path 112 and a second path 114. First path 112 adjusts a feed forward equalizer block (FFE) 116, which receives the real portion of the equalizer input 102 extracted by block 104. Second path 114 adjusts a feedback equalizer block (FBE) 118, which also receives sliced information from a slicer 124. The outputs of both FFE and 116 and FBE 118 are input into an adder 120. The added inputs are the equalizer output 122. Output 122 is further subjected to slicer 124 and supplied to FBE 118.

As can be seen, the coefficients of the decision feedback equalizer 100 for a VSB receiver such as an 8-VSB receiver could be directly calculated through the real part of the channel estimation. The coefficients can be the optimum solution for the data at exactly that moment. However, if the equalizer input data are noisy i.e. noise-to-data ratio is deemed high; it is still very difficult to generate good equalizer output data 122 before the Slicer 124. If this is the case, the Slicer 124 will make wrong decisions and the FBE output 118 will not be able to cancel the inter-symbol interferences caused by the post cursor, which is the multipath path bins after the main path of the channel impulse response. As a result, more noise in equalizer output 122 is generated. The system will go into positive feedback and eventually diverge.

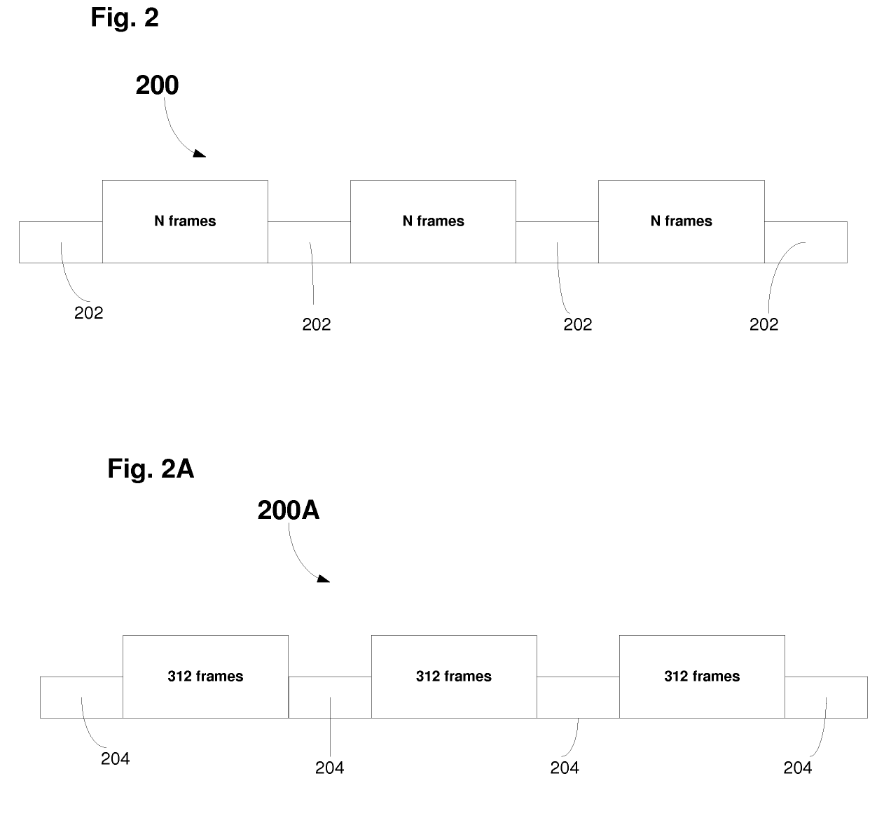

Referring to FIG. 2, a sequence of frames 200 adapted to be received by a receiver is provided. The receiver may be a multi-level variable side band (VSB) receiver. For the sequence of frames 200, there is a synchronization frame 202 interposed between every N frames, with N being a natural number greater than one. At least part of the synchronization frame consists of low level data. In FIG. 1 supra, we can use the low level data in the synchronization frame to ‘train’ the equalizer 100 first to make sure that the slicer output is accurate. The slicer 124 generates better decisions in working at low level mode during frame synchronization, as compared with using other high level modes. Better decision at the Slicer 124 in turn generates better FBE 118 output to cancel the post cursor multipath effect. Better equalizer output 122 is generated as a result. This way, equalizer 100 progresses toward negative feedback and the system eventually converges. Because the DFE coefficients are calculated from channel estimation instead of updating through decision errors, it is necessary to ‘train’ equalizer using the frame synchronization; otherwise, it will be difficult for equalizer to converge quickly.

Referring to FIG. 2A, a sequence of frames 200a adapted to be received by a receiver in an ATSC 8-VSB system is provided. For the ATSC 8-VSB system, there is a synchronization frame 204 every three hundred and thirteen (313) frames. Synchronization frame 204 is a special frame and the first eight hundred twenty (820) symbols in synchronization frame 204 are 2-level data instead of 8 level data. In the system show above, we can use the 2-level data (synchronization frame 204) to ‘train’ the equalizer first to make sure that the slicer output is accurate. Because the slicer is working at 2-level mode during frame synchronization, it will generate better decisions. Better decision at the Slicer will generate good FBE output to cancel the post cursor multipath, and then will generate better equalizer output. The equalizer will go into negative feedback more and will eventually converge the system.

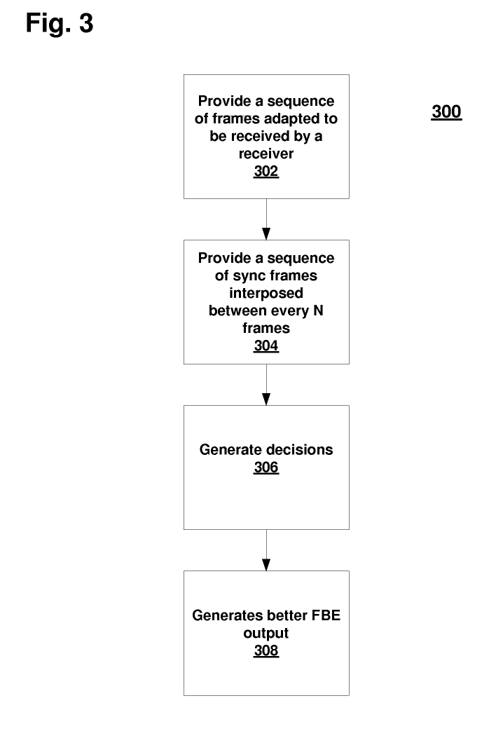

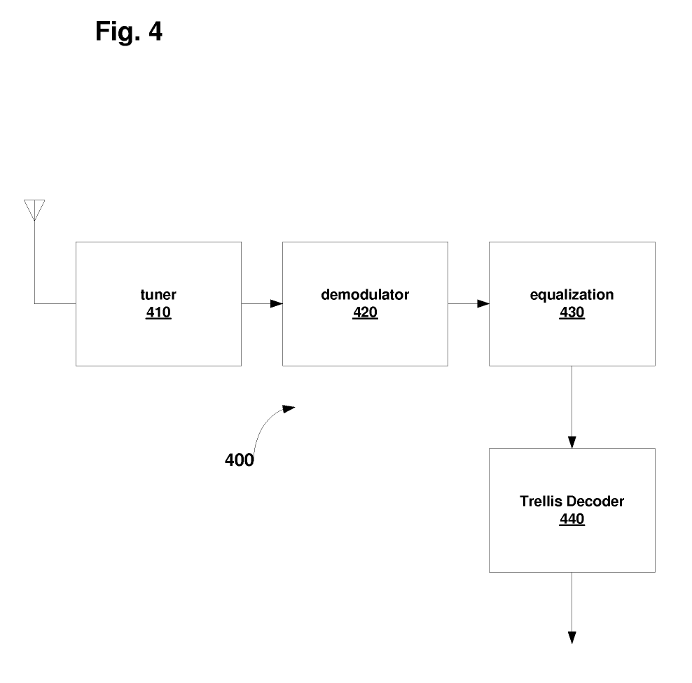

Referring to FIG. 3, flow chart 300 depicting the training process is shown. A sequence of frames adapted to be received by a receiver is provided (Step 302). The receiver may be a multi-level variable side band (VSB) receiver. Provide a sequence of synchronization frames interposed between every N frames, with N being a natural number greater than one (Step 304). At least part of the synchronization frame consists of low level data. The low level data in the synchronization frame can be used to ‘train’ the equalizer first to thereby make sure that the slicer output is accurate. Generate decisions using a slicer block at the output of the equalizer at low level mode during frame synchronization, as compared with using other high level modes for synchronization (Step 306). Generates better feedback equalizer (FBE) output to cancel the post cursor multipath effects (Step 308). Referring to FIG. 4, a block diagram of a conventional digital television receiver 400, which can process a VSB signal, is shown. The digital television receiver 400 includes a tuner 410, a demodulator 420, an equalizer 430, and a TCM (Trellis-coded Modulation) decoder 440. TCM coding may use an error correction technique, which may improve system robustness against thermal noise. TCM decoding may have more robust performance ability and/or a simpler decoding algorithm. The output signal OUT of the TCM decoder 440 may be processed by a signal processor and output as multimedia signals (e.g., display signals and/or audio signals). The present invention is suitable for application in the equalizer 430. However, the present invention is not limited in its use in receiver 400. Other suitable applications are contemplated by the present invention as well.

The decision feedback equalizer (DFE) of the present invention may be a non-updated DFE. The nature of non-updated DFE determines that the training process is necessary.

In the foregoing specification, specific embodiments of the present invention have been described. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention. The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

Terms and phrases used in this document, and variations thereof, unless otherwise expressly stated, should be construed as open ended as opposed to limiting. As examples of the foregoing: the term “including” should be read as mean “including, without limitation” or the like; the term “example” is used to provide exemplary instances of the item in discussion, not an exhaustive or limiting list thereof; and adjectives such as “conventional,” “traditional,” “normal,” “standard,” and terms of similar meaning should not be construed as limiting the item described to a given time period or to an item available as of a given time, but instead should be read to encompass conventional, traditional, normal, or standard technologies that may be available now or at any time in the future. Likewise, a group of items linked with the conjunction “and” should not be read as requiring that each and every one of those items be present in the grouping, but rather should be read as “and/or” unless expressly stated otherwise. Similarly, a group of items linked with the conjunction “or” should not be read as requiring mutual exclusivity among that group, but rather should also be read as “and/or” unless expressly stated otherwise.

What is claimed is:

1. A method comprising the steps of:
providing a sequence of frames adapted to be received by a receiver;
provide a sequence of synchronization frames interposed between a predetermined number of frames; and
using at least part of the sequence of synchronization frames to train a decision feedback equalizer (DFE), thereby speeding up system convergence or making system convergence possible.

2. The method of claim 1, wherein the DFE comprises a non-updated DFE.

3. The method of claim 1, wherein the using step generates decisions at a low level mode during frame synchronization.

4. The method of claim 1, wherein the using step generates a feedback equalizer output post cursor multipath effects.

5. The method of claim 1 is used in a VSB receiver.

6. The method of claim 1 is used in a 8-VSB receiver having synchronization frame with 2-level data.

7. A receiver comprising:
a decision feedback equalizer (DFE); and
method comprising the steps of:
providing a sequence of frames adapted to be received by the receiver;
provide a sequence of synchronization frames interposed between a predetermined number of frames; and
using at least part of the sequence of synchronization frames to train the decision feedback equalizer (DFE), thereby speeding up system convergence or making system convergence possible.

8. The receiver of claim 7, wherein the DFE comprises a non-updated DFE.

9. The receiver of claim 7, wherein the using step generates decisions at a low level mode during frame synchronization.

10. The receiver of claim 7, wherein the using step generates a feedback equalizer output post cursor multipath effects.

11. The receiver of claim 7 is a VSB receiver.

12. The receiver of claim 1 is an 8-VSB receiver having synchronization frame with 2-level data.
